(19) United States
(12) Patent Application Publication
(10) Pub. No.: US 2026/0057296 A1
(43) Pub. Date: Feb. 26, 2026

(54) SYSTEMS AND METHODS FOR GENERATING TRAINING DATA

(71) Applicants: Flor Alba Castillo, Sugar Land, TX (US); SABIC Global Technologies B.V., Bergen op Zoom (NL)

(72) Inventors: Krishnan Sankaranarayanan, Houston, TX (US); Christian Andrew Wold, Bergen OP Zoom (NL); Flor Alba Castillo, Lake Jackson, TX (US)

(21) Appl. No.: 19/105,592

(22) PCT Filed: Aug. 24, 2023
(86) PCT No.: PCT/US2023/072846

§ 371 Date: Feb. 21, 2025

Related U.S. Application Data
(60) Provisional application No. 63/373,485, filed on Aug. 25, 2022.

(51) Int. Cl. G06N 20/00

(52) U.S. Cl. CPC G06N 20/00

(57) ABSTRACT

Disclosed here are methods and systems for generating a re-training set of data based on unknown entities. In an embodiment, a method includes logging a plurality of full search queries, generating a dropout bucket, determining whether each full search query of the plurality of full search queries includes an unknown entity and/or a known entity with an unknown relationship, and populating the dropout bucket with each full search query of the plurality of full search queries determined to include the unknown entity and/or the known entity with the unknown relationship. The method further includes after a pre-selected time interval, transmitting the dropout bucket to a computing device configured to generate annotated dropout buckets and in response to reception of an annotated dropout bucket, generating a formatted file readable by a machine learning training algorithm, and re-training a machine learning model based on the formatted file.

### TECHNICAL FIELD

The present disclosure generally relates to systems and methods for generation of training data for a model and, particularly, to systems and methods for generation of training data for an entity and relationship model based on unknown entities and/or known entities with unknown or missing relationships.

### BACKGROUND

Training and validating a model, for example, an entity and relationship machine learning model, typically utilizes manually annotated documents for a given domain. Annotation and/or reading/reviewing through such documents are typically performed by subject matter experts, thus consuming considerable time and resources. New models take even longer to train, as larger sets of annotated documents are utilized for such training. Generation of such annotated documents, particularly in resource constrained enterprises, may consume considerable time and resources. Further, as new documents are encountered outside of the domain, the model may be trained utilizing the new documents. The new documents outside the domain of those used for training may decrease overall model accuracy and/or consistency. The new documents are, similar to other annotated documents noted above, manually annotated and used to re-train or further train a model.

### SUMMARY

In view of the foregoing, Applicant has recognized these problems and others in the art, and has recognized a need for enhanced systems and methods for generation of training data for a model and, particularly, for systems and methods for ongoing, substantially continuous, and/or real-time generation of training data for an entity and relationship model based on unknown entities and/or known entities with unknown or missing relationships.

The present disclosure generally relates to a system that addresses the relevant issues as described above. In particular, the system may enable ongoing, substantially continuous, and/or real-time generation of training data and re-training, further training, and/or fine-tuning of a model (for example, an entity and relationship model) with limited, minimal, substantially no, or no user interaction. Such a system may be configured to receive search queries, for example, through a user interface, from one or more computing devices. The search queries may be applied to or transmitted to a model (for example, a trained entity and relationship model or machine learning model) for analysis and/or processing. In an embodiment, a search query may include unknown entities, known entities with unknown relationships, and/or known entities with known relationships, based on the search query input at the, for example, user interface. The model may indicate, based on natural language processing (NLP) (for example, discovery or identification of noun chunks, such as nouns and words used to describe the nouns), whether such entities and/or relationships in the search query are known or unknown. If an entity and/or relationship is determined to be unknown or missing, then the system may transmit a portion of the search query (for example, the unknown entity, the known entities with unknown or missing relationships, and/or other portions of the search query) or the full search query to a dropout bucket or file. The system may continue to perform such operations (for example, adding search queries or portions of search queries to the dropout bucket or file) for a predefined or preselected period of time or time interval (or based on another factor), thus generating a dropout bucket or file with a plurality of entries. After the predefined or preselected period of time or time interval has lapsed (or other factor is met or lapsed), the dropout bucket or file may be transmitted to one or more computing devices configured to generate an annotated or marked up version of the dropout bucket or file (for example, a version of the dropout bucket or file including indications as to what the unknown entities and/or unknown or missing relationships are and/or what the unknown entities and/or unknown or missing relationships are to be labeled as). In another embodiment, the system may be configured to automatically mark up or edit the dropout bucket or file after the predefined or preselected period of time or time interval has lapsed. In yet another embodiment, a user, via the system or via the one or more configured computing devices, may mark up or edit the dropout bucket or file. In such an embodiment, the dropout bucket or file may be sorted based on frequency of inclusion of unknown entities within the dropout bucket or file (for example, search queries using the entity including the most listed unidentified entity).

Upon reception or generation of a marked up dropout bucket or file, the system may auto-format or format the dropout bucket or file. The annotation, auto-annotation, or formatting may include formatting the dropout bucket or file to a format readable in relation to a training the model or machine learning model. The formatted dropout bucket or file may be utilized to further train, re-train, or fine-tune the model or machine learning model. Upon training, re-training, or fine-tuning, the model or machine learning model may be deployed for subsequent searches. The generation and population of the dropout bucket or file; mark-up or edit of the dropout bucket or file; formatting of the marked up or edited dropout bucket or file; and training, re-training, or fine-tuning of the model or machine learning model may be an iterative and substantially continuous or on-going process. The amount or number of search queries utilized for retraining, fine tuning, further training, or for generating a new training set may include many or large numbers of search queries. For unknown or missing relationships, in addition to mark-ups, a determined or marked-up relationship may be utilized to define a new ontology and/or a relationship for two or more known entities or unknown entities.

Accordingly, an embodiment of the disclosure is directed to a method for generating a set of training data based on one or more of unknown entities or known entities with unknown or missing relationships. The method may include logging a plurality of full search queries. The method may include generating a dropout bucket. The method may include determining whether each full search query of the plurality of full search queries includes one or more of an unknown entity or a known entity with an unknown or missing relationship. The method may include populating the dropout bucket with each full search query of the plurality of full search queries determined to include one or more of the unknown entity and/or the known entity with the unknown or missing relationship. The method may include, after a pre-selected time interval or period, transmitting the dropout bucket to a computing device configured to generate marked up dropout buckets. The method may include, in response to reception of a marked up dropout bucket from the computing device, generating, based on the marked up dropout bucket, a formatted file readable by a machine learning training algorithm. The method may include training, re-training, or fine-tuning a machine learning model based on the formatted file.

In an embodiment, the method may include, prior to transmission of the dropout bucket to the computing device, determining a frequency for each unknown entity within the dropout bucket and/or a frequency for each known entity with unknown or missing relationships within the dropout bucket. The method may include sorting the dropout bucket based on the frequency for each unknown entity and/or the frequency for each known entity with unknown or missing relationships. In another embodiment, the method may include, if one of each unknown entity remains unmarked for a pre-selected time interval, transmitting each unmarked unknown entity to the computing device with a flag, the flag to indicate generation of a new ontology definition.

In another embodiment the method may include, if one of each known entity with unknown or missing relationships remain unmarked for a pre-selected time interval, transmitting each unmarked known entity with unknown or missing relationships to the computing device with a flag. The flag may indicate generation of a new ontology definition for the unknown or missing relationship. In another embodiment, the marked up dropout bucket may be based on one or more of an internal ontology, an internal enterprise ontology, and/or an organizational ontology. In an embodiment, the marked up dropout bucket may include one or more triples. The method may include inserting the triples in a knowledge graph.

In an embodiment, the method may include re-training, training, and/or fine-tuning, with or based on the formatted file, a query intent recognition algorithm. Re-training, training, and/or fine-tuning the machine learning model may increase an F-score of the machine learning model. The machine learning model may be an entity and relationship machine learning model.

Another embodiment of the disclosure is directed to system for generating a set of training or re-training data based on one or more of unknown entities or known entities with unknown or missing relationships, the system may include logging circuitry. The logging circuitry may be configured to log a plurality of full search queries. The system may include training circuitry. The training circuitry may be configured to generate a file. The training circuitry may be configured to determine whether each full search query of the plurality of full search queries includes one or more of an unknown entity or a known entity with an unknown or missing relationship. The training circuitry may be configured to populate the file with each full search query of the plurality of full search queries determined to include one or more of the unknown entity or the known entity with the unknown or missing relationship. The training circuitry may be configured to, after a pre-determined or pre-selected time interval or time period, transmit the file to a computing device configured to generate marked up files. The training circuitry may be configured, in response to reception of a marked up file: auto-format the marked up file to thereby generate a machine learning readable file; and re-train, train, and/or fine-tune an entity and relationship machine learning model with the machine learning readable file.

The training circuitry may further be configured to determine a frequency of each instance of each of the one or more unknown entities and a frequency of each instance of each of the one or more known entities with unknown or missing relationships in the file. The file may be sorted based on the frequency of each instance of each of one or more unknown entities (for example, for annotation purposes) and/or the frequency of each instance of each of one or more known entities with unknown or missing relationships.

In another embodiment, the training circuitry may be configured to determine a first time that an unknown entity remains unmarked. The training circuitry may be configured to determine a second time that known entities with unknown or missing relationships remains unmarked. The training circuitry may be configured to, in response to a determination that the first time is greater than a preselected time, define a new ontology for the unknown entity remaining unmarked. The new ontology may be defined based on input from the computing device. The training circuitry may be configured to, in response to a determination that the second time is greater than a preselected time, define a new relationship between known entities. The new relationship between known entities may be defined based on input from the computing device and/or a user's input.

Another embodiment of the disclosure is directed to a non-transitory machine-readable storage medium storing processor-executable instructions that, when executed by at least one processor, cause the at least one processor to perform an operation, process, and/or step. Execution of the instructions may cause the processor to log a plurality of full search queries. Execution of the instructions may cause the processor to generate a dropout bucket or file. Execution of the instructions may cause the processor to determine whether each full search query of the plurality of full search queries includes one or more of an unknown entity or a known entity with an unknown or missing relationship. Execution of the instructions may cause the processor to populate the file with each full search query of the plurality of full search queries determined to include one or more of the unknown entity or the known entity with the unknown or missing relationship. Execution of the instructions may cause the processor to, after a pre-determined time interval, transmit the file to a computing device configured to generate marked up files. Execution of the instructions may cause the processor to, in response to reception of a marked up file: auto-format the marked up file to thereby generate a machine learning readable file; and re-train an entity and relationship machine learning model with the machine learning readable file.

Another embodiment of the disclosure is directed to a method for generating a training set of data based on one or more of unknown entities. The method may include logging a plurality of full search queries. The method may include generating a dropout bucket. The method may include determining whether each full search query of the plurality of full search queries includes one or more of an unknown entity. The method may include populating the dropout bucket with each full search query of the plurality of full search queries with the one or more of the unknown entity. The method may include, after a pre-selected time interval, transmitting the dropout bucket to a computing device configured to generate a marked up dropout bucket. The method may include, in response to reception of the marked up dropout bucket from the computing device, generating, based on the marked up dropout bucket, a formatted file readable by a machine learning training algorithm. The method may include re-training the machine learning model based on the formatted file.

Additional and/or alternative objects, features and advantages of the present disclosure will become apparent to the skilled artisan from the figures, detailed description, and examples herein. Applicant notes, however, that the figures, detailed description, and examples, while indicating certain embodiments of the instant disclosure, are provided for illustrative purposes only and are not intended to be limiting or to imply a particular limitation. Moreover, certain changes and modifications within the spirit and scope of the disclosed technology will become apparent to those of ordinary in the relevant art from this detailed description.

### BRIEF DESCRIPTION OF THE DRAWINGS

The disclosed aspects, features and advantages of the disclosure will become better understood with regard to the following descriptions, examples, claims, and accompanying drawings. Applicant notes, however, that the drawings illustrate certain embodiments of the disclosure and should not be considered limiting with regards to the breadth and scope of the disclosure:

FIG. 1 is a schematic diagram of a system for generating a training or re-training data set, in accordance with certain embodiments of the present disclosure;

FIG. 2 is another schematic diagram of a system for generating a training or re-training data set, in accordance with certain embodiments of the present disclosure;

FIG. 3 is a flow diagram for generating a training or re-training data set, in accordance with certain embodiments of the present disclosure;

FIG. 4 is another flow diagram for training a model, in accordance with certain embodiments of the present disclosure;

FIG. 5 is a user interface (UI) for marking up or editing a dropout bucket or file, in accordance with certain embodiments of the present disclosure;

FIG. 6 is a flow diagram for generating a training or re-training data set and training, re-training, or fine-tuning a model, in accordance with certain embodiments of the present disclosure;

FIG. 7A and FIG. 7B are flow diagrams for generating a training or re-training data set and training, re-training, or fine-tuning a model, in accordance with certain embodiments of the present disclosure; and

FIG. 8A and FIG. 8B are flow diagrams for generating a training or re-training data set and training, re-training, or fine-tuning a model, in accordance with certain embodiments of the present disclosure.

### DETAILED DESCRIPTION

Additional and/or alternative objects, features and advantages of the present disclosure will become apparent to the skilled artisan from the figures, detailed description, and examples herein. Applicant notes, however, that the figures, detailed description, and examples, while indicating certain embodiments of the instant disclosure, are provided for illustrative purposes only and are not intended to be limiting or to imply a particular limitation. Moreover, certain changes and modifications within the spirit and scope of the disclosed technology will become apparent to those of ordinary in the relevant art from this detailed description.

The following definitions are provided for clarifying certain terms and phrases of the present disclosure and are in no way intended to unnecessarily or unduly limit any embodiments and aspects related thereto.

The use of the words “a” or “an” when used in conjunction with the term “comprising,” “including,” “containing,” or “having” in the claims or the specification may mean “one,” but it is also consistent with the meaning of “one or more,” “at least one,” and “one or more than one.”

The words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

So that the manner in which the features and advantages of the embodiments of the systems and methods disclosed herein, as well as others that will become apparent, may be understood in more detail, a more particular description of embodiments of systems and methods briefly summarized above may be had by reference to the following detailed description of embodiments thereof, in which one or more are further illustrated in the appended drawings, which form a part of this specification. It is to be noted, however, that the drawings illustrate only various embodiments of the systems and methods disclosed herein and are therefore not to be considered limiting of the scope of the systems and methods disclosed herein as it may include other effective embodiments as well.

Annotation or mark up and/or reading/reviewing through documents used for training, re-training, and/or fine-tuning a model is typically performed by subject matter experts, consuming considerable time and resources. Generation of such documents, particularly in resource constrained enterprises, may consume considerable time and resources. Further, as new documents are encountered outside of the domain of the model, the model may be trained using the new documents. The new documents outside the domain of those used for training may decrease overall model accuracy and/or consistency. The new documents are, similar to other documents noted above, manually annotated or marked up and used to re-train or further train a model. Accordingly, systems and methods were developed for generation of training data for a model and, particularly, to systems and methods for ongoing, substantially continuous, and/or real-time generation of training data for an entity and relationship model based on unknown entities and/or known entities with unknown or missing relationships.

Embodiments of such a system, as well as methods related thereto, are beneficially capable of improving the efficiency of training, re-training, or fine-tuning a model, while reducing time and resources used, as described herein. Further, the systems and methods described herein may improve the overall accuracy and/or F-score or F-measure (for example, the measurement of a models accuracy) of the model. In some embodiments, the system may be configured to receive a plurality of search queries from one or more computing devices (for example, search queries input into a user interface (UI) displayed, for example, via a web browser of the computing device. The system may analyze, via the model, the search queries to determine whether the search queries include one or more of unknown entities and/or known entities with unknown or missing relationships. The unknown entities and/or known entities with unknown or missing relationships may be added to a dropout bucket or file or, in another example, to separate or one or more dropout buckets or files. The dropout bucket or file may be transmitted to a computing device configured to annotate, mark up, or edit the dropout bucket or file or the system may perform the annotation, marking up, or editing of the dropout bucket or file. The system may utilize the annotated, marked up, or edited file to train, re-train, or fine-tune the model (for example, an entity and relationship model and/or a query intent recognition algorithm). The trained, re-trained, or fine-tuned model may then be deployed and utilized for subsequent search queries.

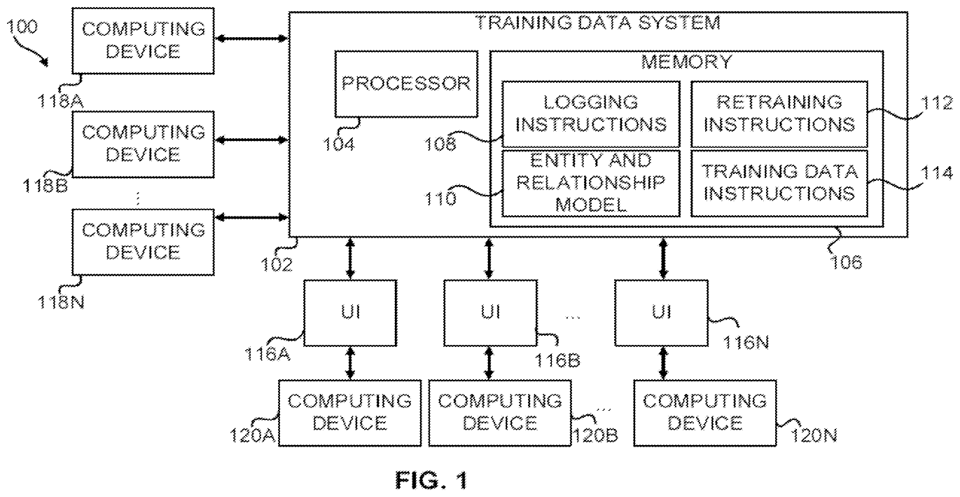

FIG. 1 is a schematic diagram of a system, in accordance with certain embodiments of the present disclosure. The system 100 may include a training data system 102 (for example, a system for generating a training set of data). The training data system 102 may include one or more processors 104 and memory 106. The memory 106 may include and/or store instructions, models and/or classifiers executable by the one or more processors 104. For example, the memory 106 may include logging instructions 108. The logging instructions 108 may, when executed by the one or more processors 104, generate a dropout bucket, a file, and/or a text file, hereinafter collectively referred to as a dropout bucket. The logging instructions 108 may generate a dropout bucket for search queries or portions of search queries with unknown entities and/or for known entities with unknown or missing relationships. In other words, the logging instructions 108 may generate a dropout bucket for search queries or portions of search queries with unknown entities and/or a dropout bucket for search queries or portions of search queries with known entities with unknown or missing relationship. In another embodiment, the logging instructions 108 may generate one dropout bucket for both search queries or portions of search queries with unknown entities and search queries or portions of search queries with known entities with unknown or missing relationships.

The logging instructions 108, when executed by the one or more processors 104, may, upon entry of a search query into a search box (for example, a search) included in a user interface (UI), for example, UI 116A, UI 116B, and up to UI 116N, determine whether the search query includes one or more of an unknown entity and/or a known entity with an unknown or missing relationship. The search may be performed via an internal search tool (for example, specific to an organization) or an external search tool (for example, available via the internet for one or more users). The internal or external search tool may be displayed to the user via the UT (for example, UT 116A, 116B, 116N), such as via a graphical user interface (GUI) or web-based user interface (WUI). As a user, via a computing device (for example, computing device 120A, computing device 120B, and/or up to computing device 120N), navigates to the internal or external search tool, the user may enter a search query and/or various terms. The search query and/or various terms may be entered to locate relevant documents (for example, documents related to the search query or various terms) or other information.

In an embodiment, to determine whether a search query includes one or more unknown entities and/or one or more known entities with unknown or missing relationships, the logging instructions 108 may transmit or apply the search query and/or various terms to the entity and relationship model 110 and/or other models or algorithms. The entity and relationship model 110 may be a trained model or classifier. The entity and relationship model 110 may be utilized to determine and/or map entities to various classifications (for example, such as, but not limited to, organization, business unit, chemical, and/or test, among other categories or classifications) and generate likely relationships between those entities. In an example, the entity and relationship model 110 may utilize natural language processing to recognize or discover noun chunks to make such a determination. Using this determination and/or mapping, along with other models and tools (for example, a query intent recognition algorithm or model, and/or a knowledge graph, among other models or tools), the search tool may generate a list of the most relevant documents or other type of results for the user. As noted, some entities in a search query and/or relationships between known entities may be unknown or missing. The model may indicate whether an entity or relationship between known entities are unknown. In such examples, the logging instructions 108 may cause the search query, a part of the search query, the unknown entity, and/or the known entities with unknown relationships to be stored in the dropout bucket. The logging instructions 108 may continue to add or log such search queries or parts of search queries for a pre-determined or pre-selected length or period of time or a time interval. For example, the new search queries or parts of search queries may be logged for an hour, a day, a week, a month, or for lesser or longer. In another embodiment, rather than logging search queries for a pre-determined or pre-selected length or period of time, search queries may be logged based on amount of search queries received, for example, search queries may be logged until fifty search queries, a hundred search queries, a thousand search queries, or more are received.

Once the pre-determined or pre-selected length or period of time or other factor has lapsed or been met, the logging instructions 108 may transmit the dropout bucket (or dropout buckets) to or process the dropout bucket (or dropout buckets) via training data instructions 114. The training data instructions 114, when executed by the one or more processors 104, may transmit the dropout bucket to one or more computing devices (for example, computing device 118A, computing device 1118B, and/or up to computing device 118N). The one or more computing devices 118A, 118B, 118N may be configured to annotate, mark up, and/or edit the dropout bucket or, in another embodiment, generate a user interface configured to display the contents of the dropout bucket in a readable format and allow for annotating, marking up, or editing of the contents of the dropout bucket. As used in herein, “annotated”, “marked up”, or “edited” may refer to a process of labeling unknown entities and/or labeling unknown relationships based on one or more ontologies (for example, an internal ontology, an internal enterprise ontology, an organizational ontology, and/or a specified ontology related to a specified organization). The computing devices 118A, 118B, 118N may annotate, mark up, or edit the dropout bucket automatically (for example, via an algorithm, script, or machine learning algorithm, instructions, or program) or may enable a user to annotate, mark up, or edit the dropout bucket or contents of the dropout bucket. In another embodiment, rather than transmitting the dropout bucket to the computing devices 118A, 118B, 118N, the training data system 102 may be configured to automatically annotate, mark up, or edit the dropout bucket or generate the user interface allowing a user to mark up or edit the dropout bucket.

In another embodiment, each search query entered or submitted via the UI 116A, 116B, 116N may be logged in a dropout bucket. Each search query may be analyzed and if a search query of the plurality of search queries does not include an unknown entity and/or known entities with unknown or missing relationships, then that search query may be removed or deleted from the dropout bucket.

In another embodiment, known entity labels and/or known relationship labels may not match or relate to any labels of the one or more ontologies utilized. In such an embodiment, the unknown entities and/or unknown relationships may remain unmarked or edited after a specified period of time. In other words, when a dropout bucket is marked up or edited, such unknown entities and/or unknown or missing relationships may remain unmarked. The unmarked unknown entities and/or unknown or missing relationships may be added to subsequent dropout buckets. In another embodiment, the training data system 102 may wait a specified or pre-selected time and, if the unknown entities and/or unknown or missing relationships remain unmarked past the specified or pre-selected time, then the training data system 102 may be configured to or may transmit the remaining unknown entities and/or unknown or missing relationships to a computing device configured to generate a new ontology definition for the unmarked unknown entities and/or unknown or missing relationships. If the training data system 102 transmits the unmarked unknown entities and/or unknown or missing relationships to a computing device, the training data system 102 may flag or include a flag corresponding to the unmarked unknown entities and/or unknown relationships. The flag may indicate that a new ontology may be added or generated for the unmarked unknown entities and/or unknown or missing relationships. In other words, the flag may indicate that an unmarked unknown entity and/or unknown or missing relationship that has remained unknown for such a length of time and that a current ontology does not exist for the unknown entities and/or unknown or missing relationships. In a further embodiment, the length of time may include a week, a month, or even longer. In yet another embodiment, the length of time may be based on the time that search queries are added to a dropout bucket and, in an example, the length of time may be greater than or equal to the time that search queries are added to a dropout bucket. In an embodiment, rather than or in addition to a length of time, other factors may be utilized to determine that a current ontology does not exist for the unknown entities and/or unknown or missing relationships, such as, but not limited to, the number of times that an unmarked unknown entity and/or an unmarked unknown or missing relationship has been reviewed and/or an indication from a computing device and/or user (for example, a computing device flags an unmarked unknown entity and/or an unmarked unknown or missing relationship to indicate that a current ontology does not exist for the unmarked unknown entity and/or an unmarked unknown or missing relationship).

The dropout bucket may be sorted prior to such transmission and/or annotation or mark up. For example, the logging instructions 108 may, when executed by the one or more processors 104, determine a frequency of each instance of each of the one or more unknown entities and a frequency of each instance of each of the one or more known entities with unknown or missing relationships in the dropout bucket. The logging instructions 108 may, when executed by the one or more processors 104, sort the dropout bucket based on the frequency of each instance of each of one or more unknown entities and/or the frequency of each instance of each of one or more known entities with unknown or missing relationships.

Once a dropout bucket has been annotated, marked up, or edited or once a dropout bucket that has been annotated, marked up, or edited has been received, the training data instructions 114 or retraining instructions 112 may, when executed by the one or more processors 104, automatically format the dropout bucket thereby defining a formatted dropout bucket or file. The training data instructions 114 or retraining instructions 112 may, when executed by the one or more processors 104, convert the dropout bucket to a format usable or readable by a machine learning model or classifier, for example, the entity and relationship model 110 and/or a query intent recognition algorithm or model. The retraining instructions 112 may, when executed by the one or more processors 104, then proceed to utilize the formatted dropout bucket to train, re-train, and/or fine-tune a machine learning model or classifier, such as the entity and relationship model 110 and/or a query intent recognition algorithm or model. Once the machine learning model or classifier, (for example, the entity and relationship model 110 and/or a query intent recognition algorithm) is trained, re-trained, and/or fine-tuned, the machine learning model or classifier (for example, the entity and relationship model 110 and/or a query intent recognition algorithm or model) may be deployed for use in subsequent searches.

In some examples, the training data system 102 may be a computing device. The term “computing device” is used herein to refer to any one or all of programmable logic controllers (PLCs), programmable automation controllers (PACs), industrial computers, servers, virtual computing device or environment, desktop computers, personal data assistants (PDAs), laptop computers, tablet computers, smart books, palm-top computers, personal computers, smartphones, virtual computing devices, cloud based computing devices, and similar electronic devices equipped with at least a processor and any other physical components necessarily to perform the various operations described herein. Devices such as smartphones, laptop computers, and tablet computers are generally collectively referred to as mobile devices.

The term “server” or “server device” is used to refer to any computing device capable of functioning as a server, such as a master exchange server, web server, mail server, document server, or any other type of server. A server may be a dedicated computing device or a server module (for example, an application) hosted by a computing device that causes the computing device to operate as a server. A server module (for example, server application) may be a full function server module, or a light or secondary server module (e.g., light or secondary server application) that is configured to provide synchronization services among the dynamic databases on computing devices. A light server or secondary server may be a slimmed-down version of server type functionality that can be implemented on a computing device, such as a smart phone, thereby enabling it to function as an Internet server (for example, an enterprise e-mail server) only to the extent necessary to provide the functionality described herein.

As used herein, a “non-transitory machine-readable storage medium” or “memory” may be any electronic, magnetic, optical, or other physical storage apparatus to contain or store information such as executable instructions, data, and the like. For example, any machine-readable storage medium described herein may be any of random access memory (RAM), volatile memory, non-volatile memory, flash memory, a storage drive (for example, a hard drive), a solid state drive, any type of storage disc, and the like, or a combination thereof. The memory may store or include instructions executable by the processor.

As used herein, a “processor” or “processing circuitry” may include, for example one processor or multiple processors included in a single device or distributed across multiple computing devices. The processor (for example, processor 104 shown in FIG. 1) may be at least one of a central processing unit (CPU), a semiconductor-based microprocessor, a graphics processing unit (GPU), a field-programmable gate array (FPGA) to retrieve and execute instructions, a real time processor (RTP), other electronic circuitry suitable for the retrieval and execution instructions stored on a machine-readable storage medium, or a combination thereof.

In an embodiment, the machine learning model or classifier (for example, the entity and relationship model 110, a query intent recognition algorithm or model, and/or other model or classifier) may be a supervised or unsupervised learning model. In an embodiment, the machine learning model or classifier may be based on one or more of decision trees, random forest models, random forests utilizing bagging or boosting (as in, gradient boosting), neural network methods, support vector machines (SVM), other supervised learning models, other semi-supervised learning models, other unsupervised learning models, or some combination thereof, as will be readily understood by one having ordinary skill in the art. In an embodiment, the entity and relationship model 110 may determine entities and/or relationships between entities via natural language processing (NLP) instructions, algorithms, or models. For example, the entity and relationship model 110 may discover or identify noun chunks, such as, for example, nouns and words used to describe the nouns. The entity and relationship model 110 may then utilize, at least, the noun chunks to identify different entities and/or the relationships between those entities.

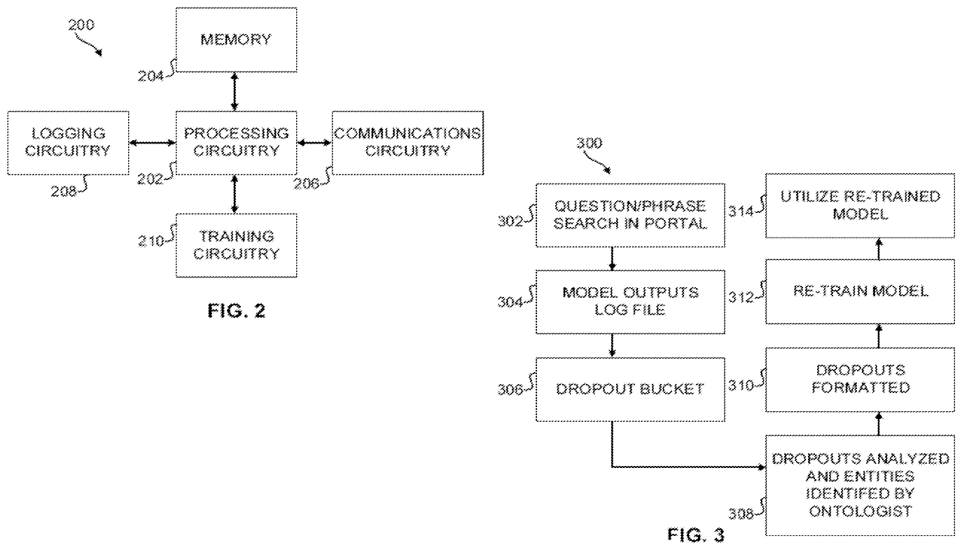

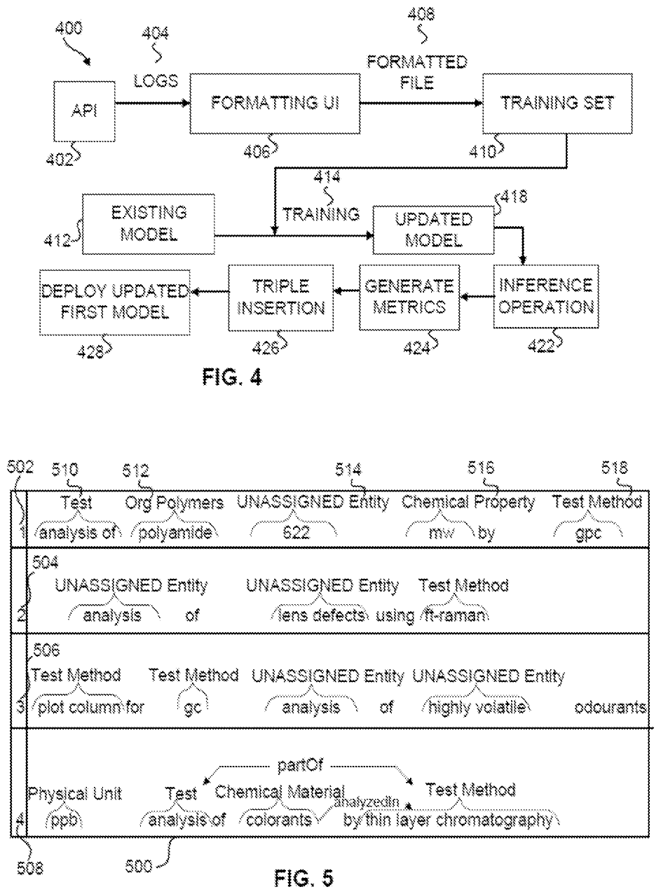

FIG. 2 is another schematic diagram of a system or apparatus for generating a training or re-training data set, in accordance with certain embodiments of the present disclosure. The apparatus 200 may include processing circuitry 202, memory 204, communications circuitry 206, logging circuitry 208, and training circuitry 210, each of which will be described in greater detail below. While the various components are only illustrated in FIG. 2 as being connected with processing circuitry 202, it will be understood that the apparatus 200 may further comprise a bus (not expressly shown in FIG. 2) for passing information amongst any combination of the various components of the apparatus 200. The apparatus 200 may be configured to execute various operations described herein, such as those described above in connection with FIG. 1 and below in connection with FIGS. 3-4 and 6-8B.

The processing circuitry 202 (and/or co-processor or any other processor assisting or otherwise associated with the processor) may be in communication with the memory 204 via a bus for passing information amongst components of the apparatus. The processing circuitry 202 may be embodied in a number of different ways and may, for example, include one or more processing devices configured to perform independently. Furthermore, the processor may include one or more processors configured in tandem via a bus to enable independent execution of software instructions, pipelining, and/or multithreading.

The processing circuitry 202 may be configured to execute software instructions stored in the memory 204 or otherwise accessible to the processing circuitry 202 (for example, software instructions stored on a separate storage device). In some cases, the processing circuitry 202 may be configured to execute hard-coded functionality. As such, whether configured by hardware or software methods, or by a combination of hardware with software, the processing circuitry 202 represents an entity (for example, physically embodied in circuitry) capable of performing operations according to various embodiments of the present disclosure while configured accordingly. Alternatively, as another example, when the processing circuitry 202 is embodied as an executor of software instructions, the software instructions may specifically configure the processing circuitry 202 to perform the algorithms and/or operations described herein when the software instructions are executed.

Memory 204 is non-transitory and may include, for example, one or more volatile and/or non-volatile memories. In other words, for example, the memory 204 may be an electronic storage device (for example, a computer readable storage medium). The memory 204 may be configured to store information, data, content, applications, software instructions, or the like, for enabling the apparatus 200 to carry out various functions in accordance with example embodiments contemplated herein.

The communications circuitry 206 may be any means such as a device or circuitry embodied in either hardware or a combination of hardware and software that is configured to receive and/or transmit data from/to a network and/or any other device, circuitry, or module in communication with the apparatus 200. In this regard, the communications circuitry 206 may include, for example, a network interface for enabling communications with a wired or wireless communication network. For example, the communications circuitry 206 may include one or more network interface cards, antennas, buses, switches, routers, modems, and supporting hardware and/or software, or any other device suitable for enabling communications via a network. Furthermore, the communications circuitry 206 may include the processing circuitry for causing transmission of such signals to a network or for handling receipt of signals received from a network.

The apparatus 200 may include logging circuitry 208 configured to generate dropout buckets, determine whether a search query includes an unknown entity and/or known entity with unknown or missing relationships, populate the dropout buckets with full or portions of search queries with unknown entities and/or known entities with unknown or missing relationships, and/or format a marked up or edited dropout bucket. The logging circuitry 208 may be configured to mark up or edit populated dropout buckets. In another embodiment, the logging circuitry 208 may be configured to transmit populated dropout buckets to one or more computing devices configured to mark up or edit populated dropout buckets. The logging circuitry 208 may utilize processing circuitry 202, memory 204, or any other hardware component included in the apparatus 200 to perform these operations, as described in connection with FIGS. 3-7B below. The logging circuitry 208 may further utilize communications circuitry 206 to gather data (for example, full or partial search queries) from a variety of sources (for example, search queries entered into a UI 116A, 116B, 116N via computing device 120A, 120B, 120N, annotated or marked up dropout buckets from computing device 118A, 118B, 118N). The output of the logging circuitry 208 may be transmitted to other circuitry of the apparatus 200 (for example, training circuitry 210).

In addition, the apparatus 200 further comprises training circuitry 210 that may format a marked up or edited dropout bucket; train, re-train, and/or fine tune a machine learning model (for example, the entity and relationship model 110 and/or a query intent recognition algorithm or model); and/or deploy the updated machine learning model. The training circuitry 210 may utilize processing circuitry 202, memory 204, or any other hardware component included in the apparatus 200 to perform these operations, as described in connection with FIGS. 3-7B below. The training circuitry 210 may further utilize communications circuitry 206 to gather data (for example, an annotated or marked up dropout bucket or a formatted and annotated or marked up dropout bucket) from a variety of sources (for example, logging circuitry 208 or computing device 118A, 118B, 118N) and in some embodiments may utilize processing circuitry 202 and/or memory 204 to format the annotated or marked up dropout bucket and/or to train, re-train, or fine-tune a machine learning model. The output of the training circuitry 210 may be transmitted to other circuitry of the apparatus 200.

Although components 202-210 are described in part using functional language, it will be understood that the particular implementations necessarily include the use of particular hardware. It should also be understood that certain of these components 202-210 may include similar or common hardware. For example, the logging circuitry 208 and training circuitry 210 may each at times leverage use of the processing circuitry 202, memory 204, or communications circuitry 206, such that duplicate hardware is not required to facilitate operation of these physical elements of the apparatus 200 (although dedicated hardware elements may be used for any of these components in some embodiments, such as those in which enhanced parallelism may be desired). Use of the terms “circuitry,” and “engine” with respect to elements of the apparatus therefore shall be interpreted as necessarily including the particular hardware configured to perform the functions associated with the particular element being described. Of course, while the terms “circuitry” and “engine” should be understood broadly to include hardware, in some embodiments, the terms “circuitry” and “engine” may in addition refer to software instructions that configure the hardware components of the apparatus 200 to perform the various functions described herein.

Although the logging circuitry 208 and training circuitry 210 may leverage processing circuitry 202, memory 204, or communications circuitry 206 as described above, it will be understood that any of these elements of apparatus 200 may include one or more dedicated processors, specially configured field programmable gate arrays (FPGA), or application specific interface circuits (ASIC) to perform its corresponding functions, and may accordingly leverage processing circuitry 202 executing software stored in a memory or memory 204, communications circuitry 206 for enabling any functions not performed by special-purpose hardware elements. In all embodiments, however, it will be understood that the logging circuitry 208 and training circuitry 210 are implemented via particular machinery designed for performing the functions described herein in connection with such elements of apparatus 200.

In some embodiments, various components of the apparatus 200 may be hosted remotely (for example, by one or more cloud servers) and thus need not physically reside on the corresponding apparatus 200. Thus, some or all of the functionality described herein may be provided by third party circuitry. For example, a given apparatus 200 may access one or more third party circuitries via any sort of networked connection that facilitates transmission of data and electronic information between the apparatus 200 and the third party circuitries. In turn, that apparatus 200 may be in remote communication with one or more of the other components describe above as comprising the apparatus 200.

As will be appreciated based on this disclosure, example embodiments contemplated herein may be implemented by an apparatus 200. Furthermore, some example embodiments may take the form of a computer program product comprising software instructions stored on at least one non-transitory computer-readable storage medium (for example, memory 204). Any suitable non-transitory computer-readable storage medium may be utilized in such embodiments, some examples of which are non-transitory hard disks, CD-ROMs, flash memory, optical storage devices, and magnetic storage devices. It should be appreciated, with respect to certain devices embodied by apparatus 200 as described in FIG. 2, that loading the software instructions onto a computing device or apparatus produces a special-purpose machine comprising the means for implementing various functions described herein.

FIG. 3 is a flow diagram for generating a training or re-training data set, in accordance with certain embodiments of the present disclosure. Unless otherwise specified, the actions of method 300 may be completed within system 100 and/or apparatus 200. Specifically, method 300 may be included in one or more programs, protocols, or instructions loaded into the memory 106 of the training data system 102 and executed on the processor or one or more processors 104. The order in which the operations are described is not intended to be construed as a limitation, and any number of the described blocks may be combined in any order and/or in parallel to implement the methods.

At block 302, a question, phrase, or various sequence of words may be entered into a search bar in a portal, such as a WUI displayed on a computing device. In an embodiment, a user may input the question, phrase, or various sequence of words.

At block 304, a logging utility may be executed. In an embodiment, execution of the logging utility may include applying the question, phrase, or various sequence of words to a model (for example, an entity and relationship model and/or a query intent recognition algorithm or model). The output of the model may be added to a text file or log file.

At block 306, a script may be executed to generate the dropout bucket including questions, phrases, or various sequences of words with unknown entities and/or known entities with unknown or missing relationships.

At block 308, the dropout bucket may be analyzed, for example, via the training data system 102 or apparatus 200. Such analysis may result in an annotated or marked up dropout bucket identifying the unknown entities and/or known entities with unknown or missing relationships. At block 310, a formatting utility may be utilized to automatically format the marked up dropout bucket. At block 312, the model (for example, an entity and relationship model and/or a query intent recognition algorithm or model) may be re-trained or fine-tuned. At block 314, the re-trained or fine-tuned model may be deployed or utilized in subsequent searches.

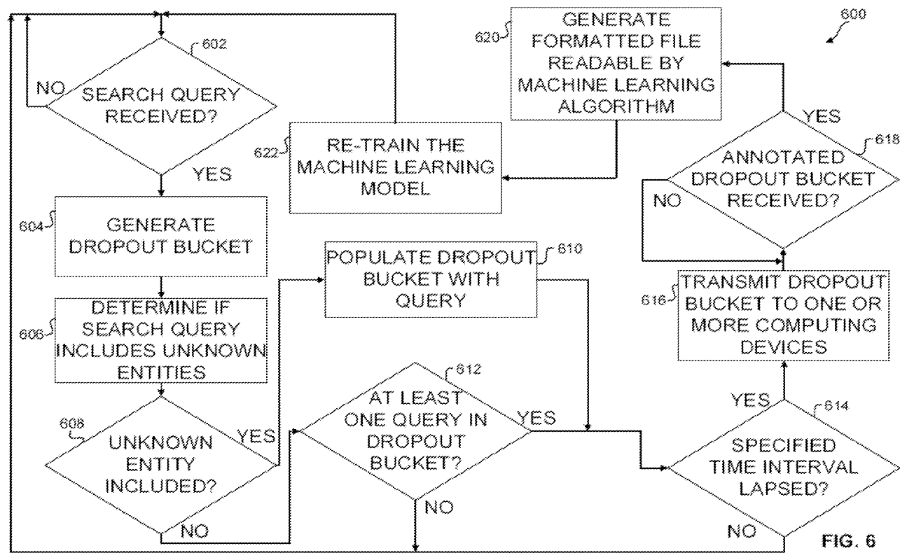

FIG. 4 is a flow diagram for training a model, in accordance with certain embodiments of the present disclosure. Unless otherwise specified, the actions of method 400 may be completed within system 100 and/or apparatus 200. Specifically, method 400 may be included in one or more programs, protocols, or instructions loaded into the memory 106 of the training data system 102 and executed on the processor or one or more processors 104. The order in which the operations are described is not intended to be construed as a limitation, and any number of the described blocks may be combined in any order and/or in parallel to implement the methods.

An application program interface (API) 402 may obtain marked up logs 404 (for example, a marked up dropout bucket from or via the training data system 102 or apparatus 200). The marked up logs 404 may be transmitted to a formatting UI 406 (for example, of the training data system 102 or apparatus 200). The formatting UI 406 may automatically format the marked up logs 404 to thereby generate a formatted file 408 (for example, a formatted and annotated or marked up log). The formatted file 408, as well as any other formatted files generated and/or available at that time, may form a training set 410. The latest version of the existing model 412 (for example, the entity and relationship model and/or a query intent recognition algorithm or model) may be obtained via a utility model script for training 414. The existing model 412 may then be trained, re-trained, or fine-tuned using the training set 410 thereby generating an updated model 418.

The updated model 418 may be used in an inference job or script 422 to obtain or generate metrics 424 based on the test set. In other words, the updated model 418 may be tested using the training set 410. At this time, at 426, any new triples (for example, two entities and a connecting relationship) may be inserted into, for example, a knowledge graph corresponding to the search tool. Finally, at block 428, the updated first model may be deployed for use in subsequent searches.

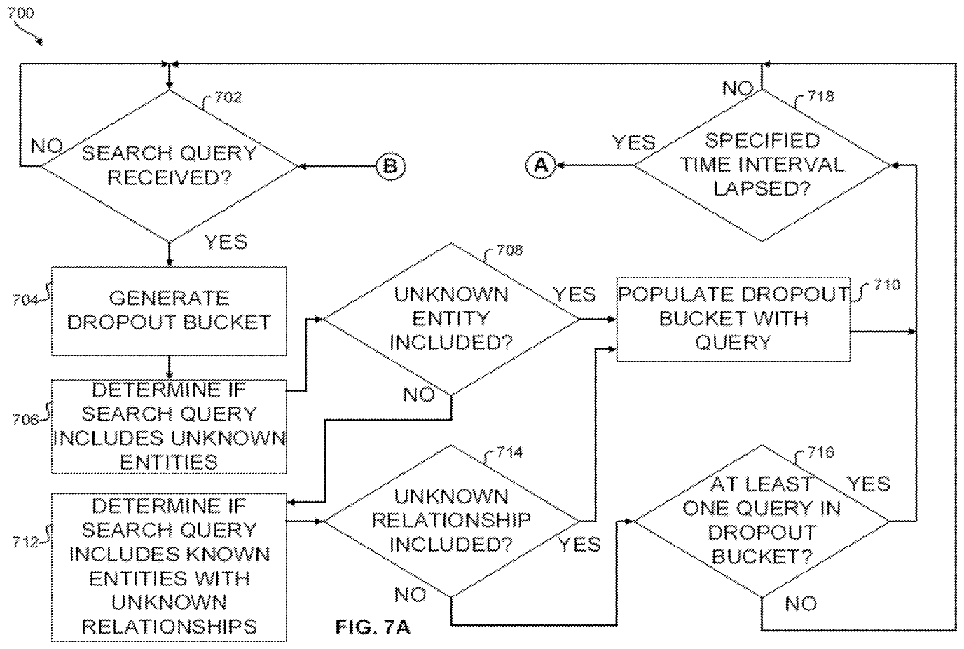

FIG. 5 is a user interface (UI) for marking up or editing a dropout bucket or file, in accordance with certain embodiments of the present disclosure. A graphical user interface (GUI) 500 is provided that illustrates an example of a partially annotated or marked up dropout bucket. In an example, the contents of the dropout bucket may be displayed to a user on one or more computing devices or, for example, the training data system via the GUI 500. While a portion of a dropout bucket is shown, it will be understood that a dropout bucket may include a plurality of search queries, for example, a hundred, a thousand, or even more search queries. Each search query may be numbered (for example, search query one 502, search query two 504, search query three 506, and search query four 508) and sorted based on various factors (for example, frequency of terms, such as, but not limited to, entities, unknown entities, and/or unknown relationships). As shown, some portions of a search query may be identified, for example, for search query one 502, at 510, “analysis of” may be identified as a test. Further, at 512, “polyamide” may be identified as “org polymers”. At 514, the number “622” may be an unassigned entity or an unknown entity. At 516, “mw” may be identified as a chemical property and, at 518, “GPC” may be identified as a test method.

In such embodiments, a user (or, in other examples, the training data system 102 or apparatus 200) may update, annotate, and/or mark up any label marked as unassigned entity and/or unassigned relationship. In another embodiment, the user may update or change any of the labels included in the GUI 500. In yet another example, the user may add labels for any unlabeled term or may add labels or identify unknown or missing relationships. For example, the user (or the training data system 102 or apparatus 200) may update, annotate, and/or mark up the unassigned entity at 514 (for example, 622). In a further example, the user (or the training data system 102 or apparatus 200) may recognize that the unassigned entity at 514 is a polyamide or, in other examples, a different defined entity. Further, the user (or the training data system 102 or apparatus 200) may update the unassigned entity at 514 to “polyamide”, thus generating a new entity (for example, based on the label “polyamide” and the word labeled as an unknown entity, “622”). In other examples, multiple words may be used to update, annotate, and/or mark up an unknown entity or unknown entities and the combination of those words and the word or words marked as an unknown entity or unknown entities may be used to generate new entities.

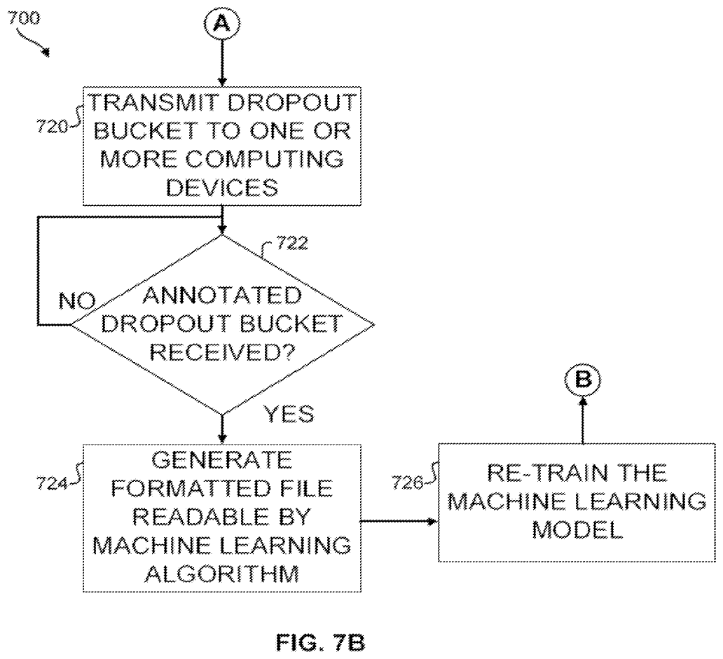

FIG. 6 is a flow diagram for generating a training or re-training data set and training, re-training, or fine-tuning a model, in accordance with certain embodiments of the present disclosure. The method 600 is detailed with reference to system 100. Unless otherwise specified, the actions of method 600 may be completed within the system 100 or training data system 102. Specifically, method 600 may be included in one or more programs, protocols, or instructions loaded into the memory 106 of the training data system 102 and executed on the processor or one or more processors 104. The order in which the operations are described is not intended to be construed as a limitation, and any number of the described blocks may be combined in any order and/or in parallel to implement the methods.

At block 602, a system (for example, the training data system 102) may determine whether a search query is received. A search query may be entered via a UI displayed on a computing device in communication with the system. The search query may be utilized by various portions of the system to generate a list of relevant results. In an embodiment, many search queries may be received at many different times. Each search query may be processed in a substantially parallel time frame or time line or as the search query is received.

At block 604, the system may generate a dropout bucket. The dropout bucket may be generated once for each analysis of multiple search queries or once overall. For example, the dropout bucket may be generated, populated, analyzed, and then deleted, a new dropout bucket replacing the previous dropout bucket. In another embodiment, the data (for example, marked up search queries) may be deleted or removed from the dropout bucket after analysis. In another embodiment, portions of the dropout bucket that have been marked up may be removed, after analysis, making space for additional search queries.

At block 606, the system may determine if the search query includes one or more unknown entities. The system may utilize a model (for example, an entity and relationship model, among other models and/or classifiers and/or a knowledge graph) to determine whether any of the terms in the search query are unknown. An indicator or label may be included in such a determination to indicate that the search query includes an unknown entity. At block 608, the system may determine whether the search query included an unknown entity based on the indicators or labels corresponding to the search query.

If the system determines that there is an unknown entity, the system may populate, at block 610, the dropout bucket with the full search query. In another embodiment, a portion of the search query may be utilized to populate the dropout bucket. In yet another embodiment, the unknown entity may be utilized to populate the dropout bucket.

At block 612, if a search query did not include an unknown entity, the system may determine whether the dropout bucket includes at least one search query. If no search queries or portion of search queries, the system may, at block 602, wait for additional search queries to be submitted. If at least one search query is included the dropout bucket, the system, at block 614, may determine if a pre-defined or pre-selected time period or interval has lapsed. If the pre-defined or pre-selected time period or interval has lapsed, the system, at block 616, may transmit the dropout bucket to one or more computing devices configured to mark up or edit the dropout bucket. In another embodiment, the system may be configured to display the dropout bucket, for annotation, mark up, or edit, to one or more users. In yet another embodiment, the system may automatically annotate, mark up, or update the dropout bucket.

At block 618, the system may check or determine whether an annotated or marked up dropout bucket has been received. In another embodiment, the system may check if the dropout bucket has been updated, annotated, marked up, or edited, rather than received. At block 620, the system may generate a formatted dropout bucket or file readable by a machine learning algorithm or model. In an embodiment, the system may format or auto format the dropout bucket. In an embodiment, search queries that are annotated or marked up may be formatted or edited. Remaining unannotated or unmarked search queries may remain in the dropout bucket, be stored in a separate dropout bucket, or deleted or removed from the dropout bucket. In other words, search queries that were not annotated or marked up may not be formatted and sent for re-training. At block 622, the system may retrain the model with the formatted file. The model may then be deployed for further use, such as in subsequent searches.

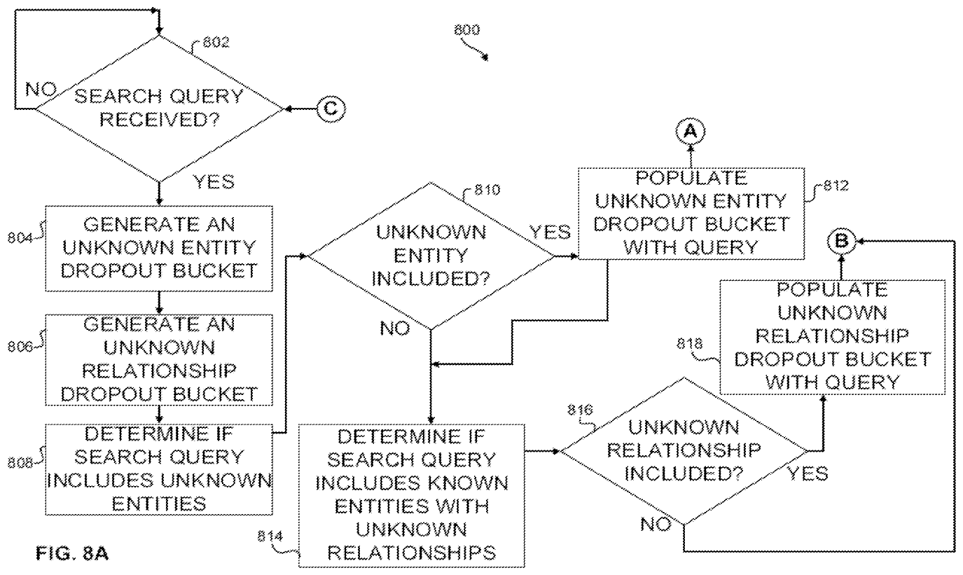

FIG. 7A and FIG. 7B are flow diagrams for generating a training or re-training data set and training, re-training, or fine-tuning a model, in accordance with certain embodiments of the present disclosure. The method 700 is detailed with reference to system 100. Unless otherwise specified, the actions of method 700 may be completed within the system 100 or training data system 102. Specifically, method 700 may be included in one or more programs, protocols, or instructions loaded into the memory 106 of the training data system 102 and executed on the processor or one or more processors 104. The order in which the operations are described is not intended to be construed as a limitation, and any number of the described blocks may be combined in any order and/or in parallel to implement the methods.

At block 702, a system (for example, the training data system 102) may determine whether a search query is received. A search query may be entered via a UI displayed on a computing device in communication with the system. The search query may be utilized by various portions of the system to generate a list of relevant results. In an embodiment, many search queries may be received at many different times. Each search query may be processed in a substantially parallel time frame or time line or as the search query is received.

At block 704, the system may generate a dropout bucket. The dropout bucket may be generated once for each analysis of multiple search queries or once overall. For example, the dropout bucket may be generated, populated, analyzed, and then deleted, a new dropout bucket replacing the previous dropout bucket. In another embodiment, the data (for example, annotated or marked up search queries) may be deleted or removed from the dropout bucket after analysis. In another embodiment, portions of the dropout bucket that have been annotated or marked up may be removed, after analysis, making room for additional search queries.

At block 706, the system may determine if the search query includes one or more unknown entities. The system may utilize a model (for example, an entity and relationship model, among other models and/or classifiers and/or a knowledge graph) to determine whether any of the terms in the search query are unknown. An indicator may be included in such a determination to indicate that the search query includes an unknown entity. At block 708, the system may determine whether the search query included an unknown entity based on the indicators corresponding to the search query.

If the system determines that there is an unknown entity, the system may populate, at block 710, the dropout bucket with the full search query. In another embodiment, a portion of the search query may be utilized to populate the dropout bucket. In yet another embodiment, the unknown entity may be utilized to populate the dropout bucket.

At block 712, if the search query did not include an unknown entity, then the system may determine whether known entities within the search query include an unknown relationship. An indicator may be included in such search queries to indicate that a search query includes an unknown relationship. In another embodiment, if the search query does not include one or more unknown entities, then the system may add the search query to the dropout bucket if a relationship is missing, potentially missing, or unknown. In other words, in such an embodiment, search queries without unknown entities and missing a relationship or including an unknown relationship may be automatically added to the dropout bucket.

At block 714, the system may, based on an included indicator, determine if the search query includes an unknown or missing relationship. If an unknown or missing relationship is included in the search query, then, at block 710, the system may populate the dropout bucket with the search query, a portion of the search query, or the known entities with the unknown or missing relationship.

At block 716, the system may determine whether the dropout bucket includes at least one search query. If not, the system may, at block 702, wait for additional search queries to be submitted. If at least one search query is included the dropout bucket, the system, at block 718, may determine if a pre-defined or pre-selected time period or interval has lapsed. If the pre-defined or pre-selected time period or interval has lapsed, the system, at block 720, may transmit the dropout bucket to one or more computing devices configured to mark up or edit the dropout bucket. In another embodiment, the system may be configured to display the dropout bucket, for mark up or edit, to one or more users. In yet another embodiment, the system may automatically mark up or update the dropout bucket.

At block 722, the system may check or determine whether an annotated or marked up dropout bucket has been received. In another embodiment, the system may check if the dropout bucket has been updated, annotated, marked up, or edited, rather than received. At block 724, the system may generate a formatted dropout bucket or file readable by a machine learning algorithm or model. In an embodiment, the system may format or auto format the dropout bucket. In an embodiment, search queries that are annotated or marked up may be formatted or edited. Remaining unannotated or unmarked search queries may remain in the dropout bucket, be stored in a separate dropout bucket, or deleted or removed from the dropout bucket. In other words, search queries that were not annotated or marked up may not be formatted and sent for re-training. At block 726, the system may retrain the model with the formatted file. The model may then be deployed for further use, such as in subsequent searches.

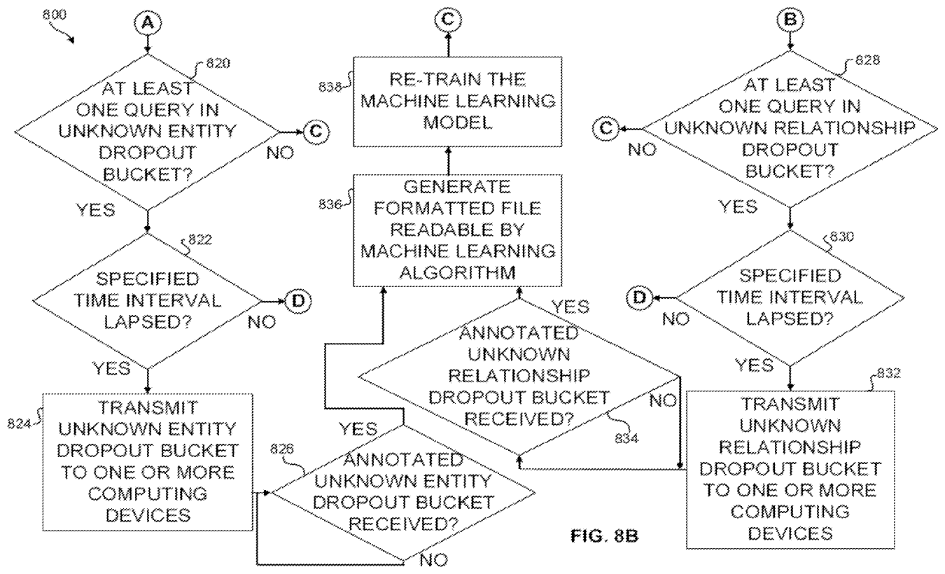

FIG. 8A and FIG. 8B are flow diagrams for generating a training or re-training data set and training, re-training, or fine-tuning a model, in accordance with certain embodiments of the present disclosure. The method 800 is detailed with reference to system 100. Unless otherwise specified, the actions of method 800 may be completed within the system 100 or training data system 102. Specifically, method 800 may be included in one or more programs, protocols, or instructions loaded into the memory 106 of the training data system 102 and executed on the processor or one or more processors 104. The order in which the operations are described is not intended to be construed as a limitation, and any number of the described blocks may be combined in any order and/or in parallel to implement the methods.

At block 802, a system (for example, the training data system 102) may determine whether a search query is received. A search query may be entered via a UI displayed on a computing device in communication with the system. The search query may be utilized by various portions of the system to generate a list of relevant results. In an embodiment, many search queries may be received at many different times. Each search query may be processed in a substantially parallel time frame or time line or as the search query is received.

At block 804, the system may generate a dropout bucket for unknown entities. The unknown entities dropout bucket may be generated once for each analysis of multiple search queries or once overall. For example, the unknown entities dropout bucket may be generated, populated, analyzed, and then deleted, a new unknown entities dropout bucket replacing the previous unknown entities dropout bucket. In another embodiment, the data (for example, annotated or marked up search queries) may be emptied from the unknown entities dropout bucket after analysis. In another embodiment, portions of the unknown entities dropout bucket that have been annotated or marked up may be removed, after analysis, making space or storage for additional search queries.

At block 806, the system may generate a dropout bucket for known entities with unknown or missing relationships. The unknown or missing relationship dropout bucket may be generated once for each analysis of multiple search queries or once overall. For example, the unknown or missing relationship dropout bucket may be generated, populated, analyzed, then deleted, a new unknown or missing relationship dropout bucket replacing the previous unknown or missing relationship dropout bucket. In another embodiment, the data (for example, annotated or marked up search queries) may be deleted or removed from the unknown or missing relationship dropout bucket after analysis. In another embodiment, portions of the unknown or missing relationship dropout bucket may be removed, after analysis, making room for additional search queries.

At block 808, the system may determine if the search query includes one or more unknown entities. The system may utilize a model (for example, the entity and relationship model, among other models and/or classifiers and/or a knowledge graph) to determine whether any of the terms in the search query are unknown. An indicator may be included in such a determination to indicate that the search query includes an unknown entity. At block 810, the system may determine whether the search query included an unknown entity based on the indicators corresponding to the search query. If the system determines that there is an unknown entity, the system may populate, at block 812, the unknown entity dropout bucket with the full search query. In another embodiment, a portion of the search query may be utilized to populate the unknown entity dropout bucket. In yet another embodiment, the unknown entity may be utilized to populate the unknown entity dropout bucket.

At block 814, the system may determine whether known entities and/or unknown entities within the search query include an unknown relationship or is missing a relationship. An indicator may be included in such search queries to indicate that a search query includes an unknown relationship or is missing a relationship (for example, no relationship is defined for two entities). At block 816, the system may, based on an included indicator, determine if the search query includes an unknown relationship or is missing a relationship. if an unknown relationship is included in or if a relationship is missing from the search query, then, at block 818, the system may populate the unknown or missing relationship dropout bucket with the search query, a portion of the search query, the known entities with the unknown or missing relationship, or unknown entities with unknown or missing relationships.

At block 820, the system may determine whether the unknown entity dropout bucket includes at least one search query. If not, the system may, at block 802, wait for additional search queries to be submitted. If at least one search query is included the unknown entity dropout bucket, the system, at block 822, may determine if a pre-defined or pre-selected time period or interval has lapsed. If the pre-defined or pre-selected time period or interval has lapsed, the system, at block 824, may transmit the unknown entity dropout bucket to one or more computing devices configured to mark up or edit the unknown entity dropout bucket. In another embodiment, the system may be configured to display the dropout bucket, for mark up or edit, to one or more users. In yet another embodiment, the system may automatically mark up or update the unknown entity dropout bucket.

At block 828, the system may determine whether the unknown or missing relationship dropout bucket includes at least one search query. If not, the system may, at block 802, wait for additional search queries to be submitted. If at least one search query is included the unknown or missing relationship dropout bucket, the system, at block 830, may determine if a pre-defined or pre-selected time period or interval has lapsed. If the pre-defined or pre-selected time period or interval has lapsed, the system, at block 832, may transmit the unknown or missing relationship dropout bucket to one or more computing devices configured to mark up or edit the unknown or missing relationship dropout bucket. In another embodiment, the system may be configured to display the unknown or missing relationship dropout bucket, for mark up or edit, to one or more users. In yet another embodiment, the system may automatically mark up or update the unknown or missing relationship dropout bucket.

At block 826, the system may check or determine whether an annotated or marked up unknown entity dropout bucket has been received. At block 834, the system may check or determine whether an annotated or marked up unknown or missing relationship dropout bucket has been received. In another embodiment, the system may check if the unknown entity dropout bucket and/or unknown or missing relationship dropout bucket have been updated, annotated, marked up, or edited, rather than received. At block 836, the system may generate a formatted file readable by a machine learning algorithm or model based on one or more of the unknown entity dropout bucket or the unknown or missing relationship dropout bucket. In an embodiment, the system may format or auto format one or more of the unknown entity dropout bucket or the unknown or missing relationship dropout bucket. In an embodiment, search queries that are annotated or marked up may be included in the formatted file. Remaining unannotated or unmarked search queries may remain in the corresponding dropout bucket, be stored in a separate dropout bucket, or deleted or removed from the dropout bucket. In other words, search queries that were not annotated or marked up may not be formatted and sent for re-training. At block 838, the system may re-train the model with the formatted file. The model may then be deployed for further use, such as in subsequent searches.

While particular terms and concepts are incorporated in the present disclosure, Applicant notes that the disclosed terms and concepts are exclusively utilized in a descriptive capacity and should not therefore be construed or interpreted as limiting in any way. Certain embodiments and aspects of the disclosed systems, processes and methods have been described in detail with particular reference to the illustrated embodiments. However, it will be apparent that numerous and various modifications and alterations may be made within the spirit and scope of the embodiments of systems, processes and methods described herein, and such modifications and changes are to be considered equivalents and within the breadth and scope of the disclosure.

1. A method for generating a training set of data for a trained machine learning model based on one or more of unknown entities or known entities with unknown relationships, the method comprising:
logging a plurality of full search queries;
generating a dropout bucket;
determining, via application of each full search query of the plurality of search queries to the trained machine learning model, whether each full search query of the plurality of full search queries includes one or more of an unknown entity or a known entity with an unknown relationship;
populating the dropout bucket with each full search query of the plurality of full search queries with the one or more of the unknown entity or the known entity with the unknown relationship;
after one or more of (a) a pre-selected amount of full search queries are populated in the dropout bucket or (b) a pre-selected time interval, transmitting the dropout bucket to a computing device configured to generate an annotated dropout bucket;
in response to reception of the annotated dropout bucket from the computing device, generating, based on the annotated dropout bucket, a formatted file readable by a machine learning training algorithm; and
re-training a trained machine learning model based on the formatted file.

2. The method of claim 1, comprising, prior to transmitting the dropout bucket to the computing device:
determining a frequency for each unknown entity within the dropout bucket;
determining a frequency for each known entity with unknown relationships within the dropout bucket;
sorting the dropout bucket based on the frequency for each unknown entity and the frequency for each known entity with unknown relationships;
in response to one of each unknown entity remaining unannotated for a pre-selected time interval, transmitting each unannotated unknown entity to the computing device with a flag, the flag to indicate generation of a new ontology; and
in response to one of each known entity with unknown relationships remaining unannotated for a pre-selected time interval, transmitting each unannotated known entity with unknown relationships to the computing device with a second flag, the second flag to indicate generation of a new relationship definition.

3. The method of claim 1, wherein the annotated dropout bucket is based on one or more of an internal ontology, an internal enterprise ontology, or an organizational ontology.

4. The method of claim 1, wherein the annotated dropout bucket includes one or more triples, and wherein comprising inserting the triples in a knowledge graph.

5. The method of claim 1, comprising:
re-training, with the formatted file, a query intent recognition algorithm.

6. The method of claim 1, wherein re-training the machine learning model increases an F-score of the machine learning model, and wherein the machine learning model is an entity and relationship machine learning model.

7. A system for generating a re-training set of data for a trained entity and relationship machine learning model based on one or more of unknown entities or known entities with unknown relationships, the system comprising:
a logging circuitry configured to log a plurality of full search queries; and
a training circuitry configured to:
generate a file,
determine whether each full search query of the plurality of full search queries includes one or more of an unknown entity or a known entity with an unknown relationship,
populate the file with each full search query with each full search query of the plurality of full search queries determined to include one or more of the unknown entity or the known entity with the unknown relationship,
after a pre-determined time interval, transmit the file to a computing device configured to generate marked up files, and
in response to reception of a marked up file:
auto-format the marked up file to thereby generate a machine learning readable file, and
re-train the trained entity and relationship machine learning model with the machine learning readable file.

8. The system of claim 7, wherein the training circuitry is configured to:
determine a frequency of each instance of each of the unknown entities and a frequency of each instance of each of the known entities with unknown relationships in the file.

9. The system of claim 7, wherein the file is sorted based on a frequency of each instance of each of the unknown entities and a frequency of each instance of each of the known entities with unknown relationships in the file.

10. The system of claim 7, wherein the training circuitry is further configured to:
determine a first time when an unknown entity remains unmarked; and
determine a second time when known entities with unknown relationships remains unmarked.

11. The system of claim 7, wherein the training circuitry is configured to:
in response to a determination that a first time when the unknown entity remains unmarked is greater than a preselected time, define a new ontology for the unknown entity remaining unmarked.

12. The system of claim 7, wherein a new ontology is defined based on input from the computing device in response to a determination that a first time when the unknown entity remains unmarked is greater than a preselected time.

13. The system of claim 7, wherein the training circuitry is configured to:
in response to a determination that a second time when known entities with unknown relationships remains unmarked is greater than a preselected time, define a new relationship between known entities.

14. The system of claim 7, wherein a new relationship between known entities is defined based on input from the computing device in response to a determination that a second time when known entities with unknown relationships remains unmarked is greater than a preselected time.

15. A method for generating a training set of data based on one or more of unknown entities, the method comprising:
logging a plurality of full search queries;
generating a dropout bucket;
determining whether each full search query of the plurality of full search queries includes one or more of an unknown entity;
populating the dropout bucket with each full search query of the plurality of full search queries with the one or more of the unknown entity;
after a pre-selected time interval, annotating the dropout bucket to generate a marked up dropout bucket;
generating, based on the marked up dropout bucket, a formatted file readable by a machine learning training algorithm; and
re-training a trained machine learning model based on the formatted file.

16. The method of claim 15, comprising, prior to annotating the dropout bucket:
determining a frequency for each unknown entity within the dropout bucket; and
sorting the dropout bucket based on the frequency for each unknown entity.

17. The method of claim 15, comprising:
in response to one of each unknown entity remaining unmarked for a pre-selected time interval, transmitting each unmarked unknown entity to a computing device with a flag, the flag to indicate generation of a new ontology.

18. The method of claim 15, wherein the marked up dropout bucket is based on one or more of an internal ontology, an internal enterprise ontology, or an organizational ontology.

19. The method of claim 15, wherein the marked up dropout bucket includes one or more triples, and wherein further comprising inserting the triples in a knowledge graph.

20. The method of claim 15, further comprising:
re-training, with the formatted file, a query intent recognition algorithm.
